(19) United States
(12) Patent Application Publication
(10) Pub. No.: US 2004/0085116 A1
(43) Pub. Date: May 6, 2004

(54) Circuit for combining on/off key and warm boot key to obtain a function of cold boot key in a portable information device

(75) Inventors: Show-Nan Chung, Sinjhuang City (TW); Chin-Peng Tsai, Sindian City (TW)

Correspondence Address: BACON & THOMAS, PLLC, 625 SLATERS LANE, FOURTH FLOOR, ALEXANDRIA, VA, 22314

(73) Assignee: Tatung Co., Ltd., Taipei City (TW)

(21) Appl. No.: 10/692,677

(22) Filed: Oct. 27, 2003

(30) Foreign Application Priority Data
Nov. 9, 2001 (TW) 90219362

(51) Int. Cl. H03K 17/687

(52) U.S. Cl. 327/427

(57) ABSTRACT

A circuit for combining on/off key and warm boot key to obtain a function of cold boot key in a portable information device is disclosed, which uses an on/off key to control a first switch circuit to be on and off and a warm boot key to control a second switch circuit to be on and off. The first switch circuit has the on/off key capable of restoring boot and halt functions. The second switch circuit has warm boot function. As the on/off key and the warm boot key are pressed at the same time, the first switch circuit and the second switch circuit are simultaneously turned on to drive a switch driving circuit to be active and thus the switch driving circuit outputs a signal to cold boot a connected portable information device.

### BACKGROUND OF THE INVENTION

1. Field of the Invention

The present invention relates to a boot circuit device and, more particularly, to a circuit adapted for combining on/off key and warm boot key to obtain a function of cold boot key in a portable information device.

2. Description of Related Art

Upon continuously improved information industry, portable information products have widely increased in use. However, for a portable information device, there are three available boot types: using the on/off key to restart the device, using a warm boot key to resume the device, and using a cold boot key to restart the device. Boot with on/off key applies an interrupt signal to wake up hibernation systems. Boot with warm boot key will save system information in the memory at re-startup and clear data temporarily stored in the memory. Boot with cold boot key will clear all system information in the memory. In existing portable information products, boot with cold boot key is performed by power-off (demounting a cell) or pressing a hardware reset key. The reset key is provided by opening a reset hole on the case and thus increases mechanism complexity. The power-off is not convenient in use for a user. Further, many people confuse functions of cold and warm boot keys, which causes inconvenient in use. Therefore, it is desirable to provide an improved boot circuit to mitigate and/or obviate the aforementioned problems.

### SUMMARY OF THE INVENTION

The object of the present invention is to provide a circuit for combining on/off key and warm boot key to obtain a function of cold boot key in a portable information device, thereby reducing complexity of product and increasing convenience of use for a user.

To achieve the object of the present invention, the circuit for combining on/off key and warm boot key to obtain a function of cold boot key in a portable information device includes a first switch circuit, a second switch circuit and a switch driving circuit. The first switch circuit is controlled by on/off key for turning on and off. The second switch circuit is connected to the first switch circuit, and controlled by warm boot key for turning on and off. The switch driving circuit is connected to the first switch circuit and the second switch circuit, and has an output terminal connected to a reset pin of a central processing unit (CPU). Thus, when the switch driving circuit is turned on after both the first switch circuit and the second switch circuit are both turned off, the output terminal can output a signal to cold boot the portable information device.

Other objects, advantages, and novel features of the invention will become more apparent from the following detailed description when taken in conjunction with the accompanying drawings.

### BRIEF DESCRIPTION OF THE DRAWINGS

FIG. 1 is a schematic diagram of a boot circuit in accordance with the invention.

### DETAILED DESCRIPTION OF THE PREFERRED EMBODIMENT

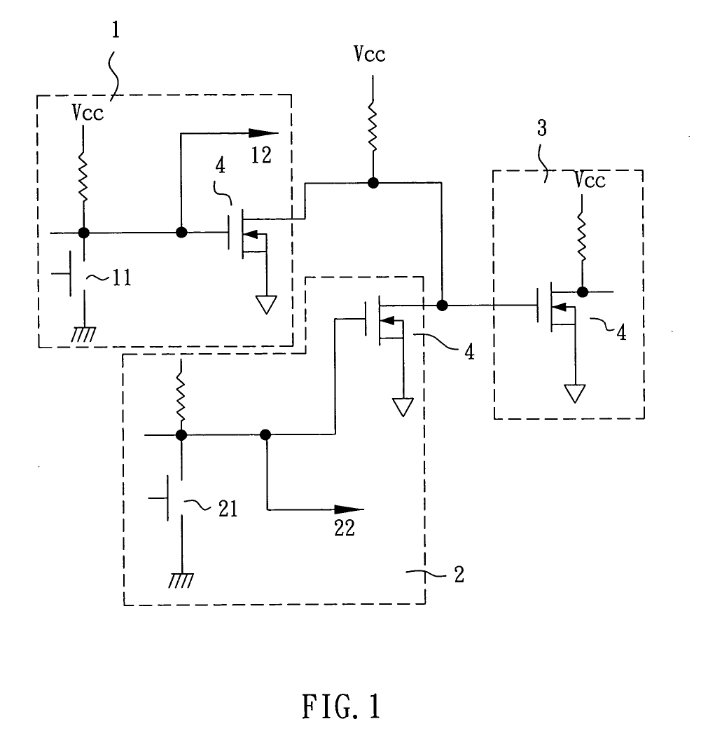

With reference to FIG. 1, there is shown a schematic diagram of a circuit for combining on/off key and warm boot key to obtain a function of cold boot key in a portable information device. In FIG. 1, the circuit consists of a first switch circuit 1, a second switch circuit 2 and a switch driving circuit 3. The first switch circuit 1 has an on/off key 11. The second switch circuit 2 has a warm boot key 21. The on/off key 11 and warm boot key 21 are bouncing type keys which can resume to the original status after being pressed.

The first switch circuit 1 consists of an N-type metal oxide semiconductor field effect transistor (NMOSFET) 4 and an interrupt line 12 connected to a first pin of interrupt signals of a CPU. The on/off key 11 controls the first switch circuit 1 to be on and off. The second switch circuit 2 connected in parallel with the first switch circuit 1 consists of an NMOSFET 4 and an interrupt line 22 connected to a second pin of interrupt signals of the CPU. The warm boot key 21 controls the second switch circuit 2 on and off. Drains of the NMOSFETs 4 of the switch circuits 1 and 2 are connected in parallel. The switch driving circuit 3 connected in parallel with the switch circuits 1 and 2 also has an NMOSFET 4. All sources of the NMOSFETs 4 are directly grounded. An output terminal of the switch driving circuit 3 is connected to a reset pin of the CPU, with low active.

When the on/off key 11 of the first switch circuit 1 is not pressed, the NMOSFET 4 of the first switch circuit 1 is turned on, and the interrupt line 12 is at a high level. When the on/off key 11 is pressed, the NMOSFET 4 of the first switch circuit 1 is turned off, and the interrupt line 12 is at a low level, so as to enable a CPU (not shown). That is, with the active low of the interrupt line 12, an interrupt signal is issued to a first interrupt signal pin of the CPU to make system enter a halt state (sleeping mode). System will be re-started up when the key 11 is pressed again and return quickly back to conditions before system halt. The latest system information is stored in memory immediately before system is halt, thus corresponding screen can display the latest system information as soon as system re-starts.

When the warm boot key 21 of the second switch circuit 2 is not pressed, the interrupt signal line 22 is at a high level. When the warm boot key 21 is pressed, the NMOSFET 4 of the second switch circuit 2 is turned off, and the interrupt line 22 is at a low level, so as to enable a CPU (not shown). That is, with the active low of the interrupt line 22, an interrupt signal is issued to a second interrupt signal pin of the CPU, such that system information is kept in memory but data temporarily stored in the memory is clear, thereby achieving the prior warm boot.

When the keys 11 and 21 are pressed at the same time, the NMOSFETs 4 of the circuits 1 and 2 are both turned off, such that the NMOSFET 4 of the switch driving circuit 3 is turned on, resulting in a low level for the output terminal of the circuit 3 to enable the reset pin connected to the CPU and thus produce cold boot effect.

In view of the foregoing, it is known that the invention provides the cold boot function by simultaneously pressing the first switch circuit 1 and the second switch circuit 2. The first switch circuit 1 has the on/off key 11 to control a function of system halt. When only the on/off key 11 is pressed, system re-startup can be obtained. The second switch circuit 2 has the warm boot key 21 to control the circuit 2 active or not. When only the warm boot key 21 is pressed, system warm boot is obtained.

Although the present invention has been explained in relation to its preferred embodiment, it is to be understood that many other possible modifications and variations can be made without departing from the spirit and scope of the invention as hereinafter claimed.

What is claimed is:

1. A circuit for combining on/off key and warm boot key to obtain a function of cold boot key in a portable information device, comprising:
a first switch circuit, which is controlled by the on/off key for turning on and off;
a second switch circuit, which is connected to the first switch circuit and controlled by the warm boot key for turning on and off; and
a switch driving circuit, which is connected in parallel with the first switch circuit and the second switch circuit and has an output terminal connected to a reset pin of a central processing unit (CPU), such that the switch driving circuit is turned on when the first switch circuit and the second switch circuit are simultaneously turned off, and the output terminal thus outputs a signal to cold boot the portable information device.

2. The circuit as claimed in claim 1, wherein the on/off key connected by the first switch circuit provides a sleeping mode to display latest system information before shut-down on a screen of the portable information device as soon as system re-starts.

3. The circuit as claimed in claim 1, wherein the warm boot key connected by the second switch circuit sends an interrupt signal to the CPU when system re-boots, so as to store system information in memory and clear temporary data in the memory.

4. The circuit as claimed in claim 1, wherein each of the first switch circuit, the second switch circuit and the switch driving circuit consists of an NMOSFET.

5. The circuit as claimed in claim 4, wherein drains of the first switch circuit and the second switch circuit are connected in parallel and connected to a gate of the switch driving circuit.

6. The circuit as claimed in claim 4, wherein sources of the first switch circuit, the second switch circuit and the switch driving circuit are all grounded directly.

7. The circuit as claimed in claim 1, wherein the first switch circuit has a line connected to a first pin of interrupt signal of the CPU, to send an interrupt signal to the CPU for reset.

8. The circuit as claimed in claim 1, wherein the second switch circuit has a line connected to a second pin of interrupt signal of the CPU, to send an interrupt signal to the CPU.
